(19) United States
(12) Patent Application Publication
(10) Pub. No.: US 2026/0169561 A1
(43) Pub. Date: Jun. 18, 2026

(54) DRIVE CIRCUIT AND HAPTIC FEEDBACK SYSTEM

(71) Applicants: Beijing BOE Technology Development Co., Ltd., Beijing (CN); BOE Technology Group Co., Ltd., Beijing (CN)

(72) Inventors: Zhihui CHEN, Beijing (CN); Jijing HUANG, Beijing (CN); Yongchun TAO, Beijing (CN)

(21) Appl. No.: 18/711,033

(22) PCT Filed: Jul. 24, 2023
(86) PCT No.: PCT/CN2023/108884

§ 371 Date: May 16, 2024

(51) Int. Cl. G06F 3/01; G06F 3/044; H03F 3/45

(52) U.S. Cl. CPC G06F 3/016; G06F 3/0446; H03F 3/45475

(57) ABSTRACT

A drive circuit and a haptic feedback system. The drive circuit includes a voltage amplification circuit and a current amplification circuit. The voltage amplification circuit is electrically connected to a signal input end and a signal output end and configured to amplify a voltage at the signal input end and output an amplified voltage to the signal output end. The current amplification circuit is electrically connected to an intermediate node and the signal output end and configured to input a compensation current to the signal output end, so that a current at the signal output end is a sum of a current at the signal input end and the compensation current. A current at the intermediate node equals the current at the signal input end.

### CROSS REFERENCE TO RELATED APPLICATION

This application is a National Stage of International Application No. PCT/CN2023/108884 filed Jul. 24, 2023, the entire contents of which are incorporated herein by reference.

### TECHNICAL FIELD

The disclosure relates to the field of an in-vehicle technology, and in particular to a drive circuit and a haptic feedback system.

### BACKGROUND

Vibration feedback, typically serving as haptic feedback of a large in-vehicle central control screen, enables a user to interact with the large in-vehicle central control screen.

For example, a mechanism-amplifying piezoelectric ceramic is typically used as a vibration actuator for the haptic feedback in the large in-vehicle central control screen. When a vibration carrier has a large mass, a drive signal carrying a high voltage and a high current has to be provided in pursuit of a desirable vibration effect.

### SUMMARY

A drive circuit and a haptic feedback system are provided in embodiments of the disclosure, so as to solve the technical problem of an insufficient drive capacity of a vibration actuator in a large in-vehicle central control screen in the related art.

In order to solve the above technical problem, in a first aspect, a drive circuit is provided in embodiments of the disclosure. The drive circuit includes:
a voltage amplification circuit, here the voltage amplification circuit is electrically connected to a signal input end and a signal output end and configured to amplify a voltage at the signal input end and output an amplified voltage to the signal output end; and
a current amplification circuit, here the current amplification circuit is electrically connected to an intermediate node and the signal output end and configured to input a compensation current to the signal output end, so that a current at the signal output end is a sum of a current at the signal input end and the compensation current, and a current at the intermediate node equals the current at the signal input end.

In some embodiments, the voltage amplification circuit includes:
an operational amplifier, here a non-inverting input end of the operational amplifier is electrically connected to the signal input end, an output end of the operational amplifier is electrically connected to the intermediate node, and two power source ends of the operational amplifier are electrically connected to a positive power source and a negative power source respectively;
a feedback circuit, here the feedback circuit is electrically connected to the signal output end and an inverting input end of the operational amplifier and configured to feed back a voltage at the signal output end to the inverting input end of the operational amplifier; and
a first resistor, here the first resistor is connected between the inverting input end and a grounded end.

In some embodiments, the feedback circuit includes a second resistor.

In some embodiments, the current amplification circuit includes:
at least one first current amplification circuit, here a control end of the first current amplification circuit is electrically connected to the intermediate node, a first end of the first current amplification circuit is electrically connected to the positive power source, and an output end of the first current amplification circuit is electrically connected to the signal output end; and the first current amplification circuit is configured to input a compensation current greater than 0 A to the signal output end in response to a potential difference between the intermediate node and the signal output end under the condition that a voltage at the intermediate node is greater than 0 V; and
at least one second current amplification circuit, here a control end of the second current amplification circuit is electrically connected to the intermediate node, a second end of the second current amplification circuit is electrically connected to the negative power source, and an output end of the second current amplification circuit is electrically connected to the signal output end; and the second current amplification circuit is configured to input a compensation current smaller than 0 A to the signal output end in response to a potential difference between the intermediate node and the signal output end under the condition that a voltage at the intermediate node is smaller than 0 V.

In some embodiments, the current amplification circuit further includes:
a third resistor, here the third resistor is electrically connected to the intermediate node and the signal output end; and the third resistor is configured to hinder the potential difference between the intermediate node and the signal output end from approximating 0 V in response to determining that the first current amplification circuit or the second current amplification circuit works, and output the current at the intermediate node to the signal output end in response to determining that the first current amplification circuit or the second current amplification circuit does not work.

In some embodiments, the first current amplification circuit includes:
a first thin film transistor, here a first electrode of the first thin film transistor is electrically connected to the positive power source;
a fourth resistor, here the fourth resistor is electrically connected between the intermediate node and a control electrode of the first thin film transistor; and
a fifth resistor, here the fifth resistor is electrically connected between a second electrode of the first thin film transistor and the signal output end.

In some embodiments, the second current amplification circuit includes:
a second thin film transistor, here a first electrode of the second thin film transistor is electrically connected to the negative power source;
a sixth resistor, here the sixth resistor is connected between the intermediate node and a control electrode of the second thin film transistor; and
a seventh resistor, where the seventh resistor is connected between a second electrode of the second thin film transistor and the signal output end.

In some embodiments, resistance of the fourth resistor equals resistance of the sixth resistor; and resistance of the fifth resistor equals resistance of the seventh resistor.

In some embodiments, the first thin film transistor and the second thin film transistor are bipolar junction transistors or metal-oxide-semiconductor field-effect transistors.

In some embodiments, the metal-oxide-semiconductor field-effect transistors include an enhancement mode metal-oxide-semiconductor field-effect transistor and a depletion mode metal-oxide-semiconductor field-effect transistor.

In some embodiments, resistance of the third resistor is smaller than 1 kΩ.

In some embodiments, in response to determining that the current amplification circuit includes k first current amplification circuits, the compensation current output by the current amplification circuit is k times a current output by one of the first current amplification circuits, and k is an integer greater than 1.

In some embodiments, in response to determining that the current amplification circuit includes M second current amplification circuits, the compensation current output by the current amplification circuit is M times a current output by one of the second current amplification circuits, and M is an integer greater than 1.

In some embodiments, a quantity of the first current amplification circuits equals a quantity of the second current amplification circuits.

In some embodiments, a ratio of the voltage at the signal output end to the voltage at the signal input end is a sum of a ratio of resistance of the second resistor to resistance of the first resistor and 1.

In a second aspect, a haptic feedback system is provided in an embodiment of the disclosure. The haptic feedback system includes:
a haptic feedback display screen;
a detection module, here the detection module is configured to detect whether the haptic feedback display screen is touched by a toucher and generate a corresponding digital signal in response to determining that the haptic feedback display screen is touched by the toucher;
a micro-control unit, here the micro-control unit is configured to determine whether a numerical value corresponding to the digital signal is greater than a preset value after receiving the digital signal, and output a drive signal in response to determining that the numerical value is greater than the preset value; and
the drive circuit in the first aspect, here the drive circuit is configured to receive the drive signal through the signal input end, process the drive signal, and output a processed drive signal to the haptic feedback display screen through the signal output end, so as to drive the haptic feedback display screen to work.

In some embodiments, the haptic feedback system further includes: a port module, here the micro-control unit receives a control instruction sent by an upper computer through the port module, the micro-control unit is allowed to output the drive signal or prohibited from outputting the drive signal according to the control instruction; and
a power source module, here the power source module is configured to supply power to the haptic feedback display screen, the detection module, the micro-control unit, the drive circuit, and the port module.

### BRIEF DESCRIPTION OF FIGURES

FIG. 1 is a schematic structural diagram of a haptic feedback system according to an embodiment of the disclosure.

FIG. 2A illustrates some schematic structural diagrams of a haptic feedback panel according to an embodiment of the disclosure.

FIG. 2B illustrates some other schematic structural diagrams of a haptic feedback panel according to an embodiment of the disclosure.

FIG. 2C illustrates yet some other schematic structural diagrams of a haptic feedback panel according to an embodiment of the disclosure.

FIG. 2D illustrates yet some other schematic structural diagrams of a haptic feedback panel according to an embodiment of the disclosure.

FIG. 2E illustrates still some other schematic structural diagrams of a haptic feedback panel according to an embodiment of the disclosure.

FIG. 3 is a sectional schematic structural diagram in direction CC′ of the haptic feedback panel shown in FIG. 2A.

FIG. 4 is a sectional schematic structural diagram of a piezoelectric device according to an embodiment of the disclosure.

FIG. 5 is a schematic structural diagram of another haptic feedback system according to an embodiment of the disclosure.

FIG. 6 is a schematic structural diagram of a drive circuit according to an embodiment of the disclosure.

FIG. 7 is a schematic structural diagram of a voltage amplification circuit according to an embodiment of the disclosure.

FIG. 8 is a schematic structural diagram of another voltage amplification circuit according to an embodiment of the disclosure.

FIGS. 9 and 10 are schematic structural diagrams of a current amplification circuit according to an embodiment of the disclosure.

FIG. 11 is a schematic structural diagram of another current amplification circuit according to an embodiment of the disclosure.

FIG. 12 is a schematic structural diagram of a first current amplification circuit according to an embodiment of the disclosure.

FIG. 13 is a schematic structural diagram of another drive circuit according to an embodiment of the disclosure.

### REFERENCE NUMERALS

Haptic feedback display screen 100, detection module 200, micro-control unit 300, drive circuit 400, port module 500, power source module 600, base substrate 1, piezoelectric device 2, touch layer 3, touch electrode 31, bottom electrode 21, top electrode 22, piezoelectric layer 23, insulation layer 25, wiring layer 26, bonding electrode 24, first via hole V1, second via hole V2, haptic detection piezoelectric device 021, haptic drive piezoelectric device 022, lead electrode 025, lead electrode via hole 41, first connection portion 0221, haptic detection signal line 321, haptic drive signal line 322, support layer 4, and support portion 411;
voltage amplification circuit 1′, current amplification circuit 2′, operational amplifier 11′, feedback circuit 12′, first resistor R1, second resistor R2, first current amplification circuit 21′, second current amplification circuit 22′, first thin film transistor TFT1, second thin film transistor TFT2, third resistor R3, fourth resistor R4, fifth resistor R5, sixth resistor R6, seventh resistor R7, signal input end IN, signal output end OUT, intermediate node A, non-inverting input end +, inverting input end −, positive power source +VCC, negative power source-VCC, control end a, first end b, output end c, and second end d.

### DETAILED DESCRIPTION

A drive circuit and a haptic feedback system are provided in embodiments of the disclosure, so as to solve the technical problem of an insufficient drive capacity of a vibration actuator in a large in-vehicle central control screen in the related art.

In order to make the above objectives, features, and advantages of the disclosure clearer and more understandable, the disclosure will be further described below in conjunction with the accompanying drawings and the embodiments. However, the illustrative implementation modes can be embodied in various forms and should not be interpreted as being limited to the implementation modes set forth herein. Rather, by providing these implementation modes, the disclosure is more thorough and complete, and the concept of the illustrative implementation modes will be fully conveyed to a person skilled in the art. The same reference numerals in the accompanying drawings denote the same or similar structures, and thus their repetition will be omitted. The words expressing positions and directions described in the disclosure are described with the accompanying drawings as examples but can also be changed as required, and the changes made fall within the scope of protection of the disclosure. The accompanying drawings of the disclosure are merely for illustrating relative position relations and are not intended to represent true proportions.

It should be noted that specific details are set forth in the following description to facilitate thorough understanding of the disclosure. However, the disclosure can be implemented in many other ways than those described herein, and a person skilled in the art can make similar extensions without departing from the intension of the disclosure. The disclosure is therefore not limited by the specific implementation modes disclosed below.

Hereafter, the description describes preferred implementation modes for implementing the disclosure, and the description is intended to illustrate the general principles of the disclosure instead of limiting the scope of the disclosure. The scope of protection of the disclosure should be defined by the appended claims.

The drive circuit and the haptic feedback system according to the embodiments of the disclosure are described below in conjunction with the accompanying drawings.

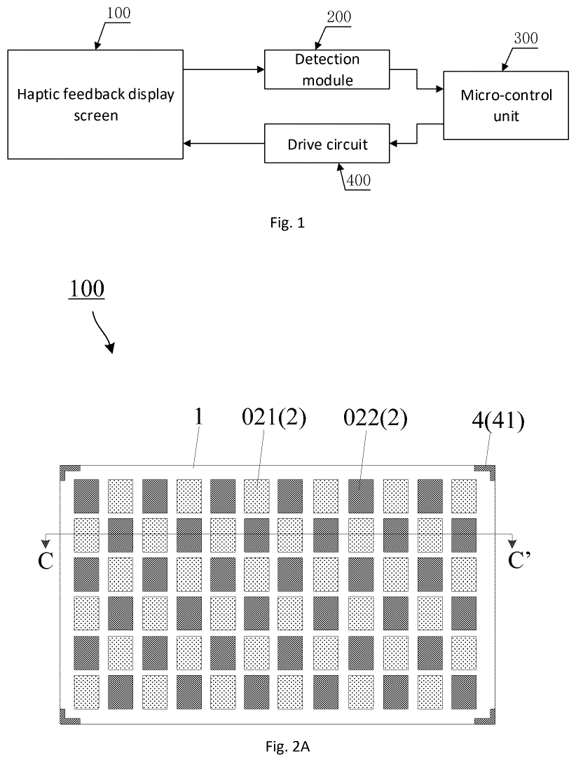

With reference to FIG. 1, a schematic structural diagram of a haptic feedback system according to an embodiment of the disclosure is illustrated. The haptic feedback system includes:
a haptic feedback display screen 100;
a detection module 200, here the detection module is configured to detect whether the haptic feedback display screen 100 is touched by a toucher and generate a corresponding digital signal in response to determining that the haptic feedback display screen is touched by the toucher;
a micro-control unit 300, here the micro-control unit is configured to determine whether a numerical value corresponding to the digital signal is greater than a preset value after receiving the digital signal, and output a drive signal in response to determining that the numerical value is greater than the preset value; and
a drive circuit 400, here the drive circuit 400 is configured to receive the drive signal through a signal input end, process the drive signal, and output a processed drive signal to the haptic feedback display screen 100 through a signal output end, so as to drive the haptic feedback display screen 100 to work. The structure of the drive circuit 400 will be described in embodiments about the drive circuit 400 below, and will not be described in detail herein.

Illustratively, the haptic feedback display screen according to the embodiments of the disclosure may be applied to automotive electronics. Specifically, the haptic feedback display screen may be configured for an in-vehicle central control screen, an in-vehicle display screen, etc. When a user touches the haptic feedback display screen, for example, for verifying a fingerprint, inputting content through a virtual key on the screen, and the like, a vibration actuator arranged inside the haptic feedback display screen may generate vibration and haptic feedback of a mechanical characteristic and feed back to the display screen. The above vibration actuator is driven by the drive circuit.

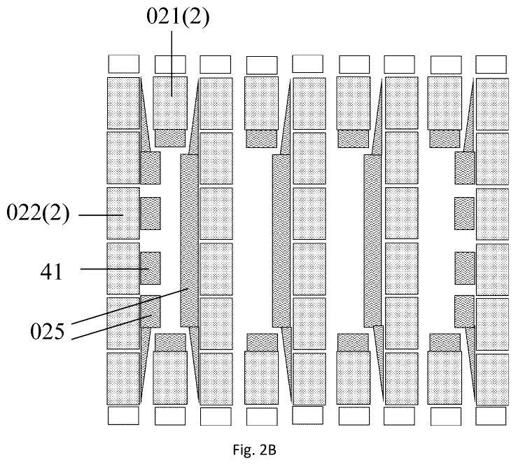

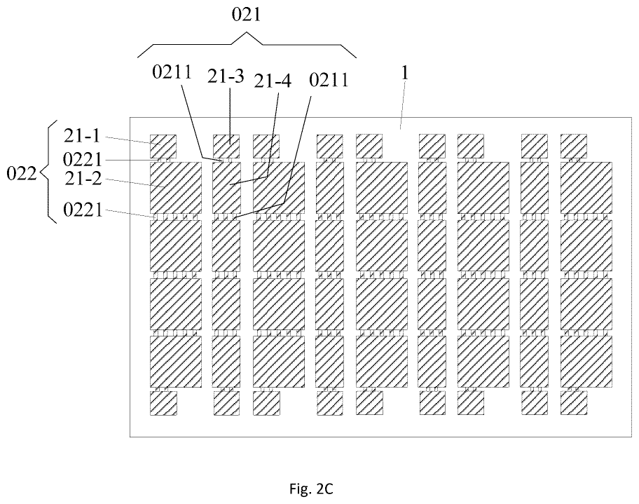

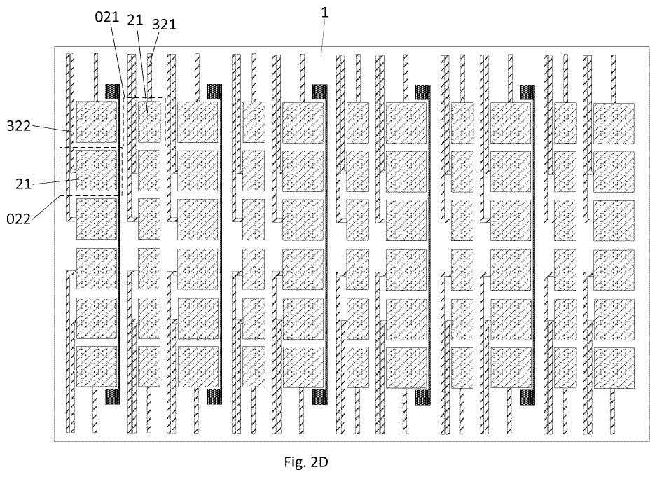

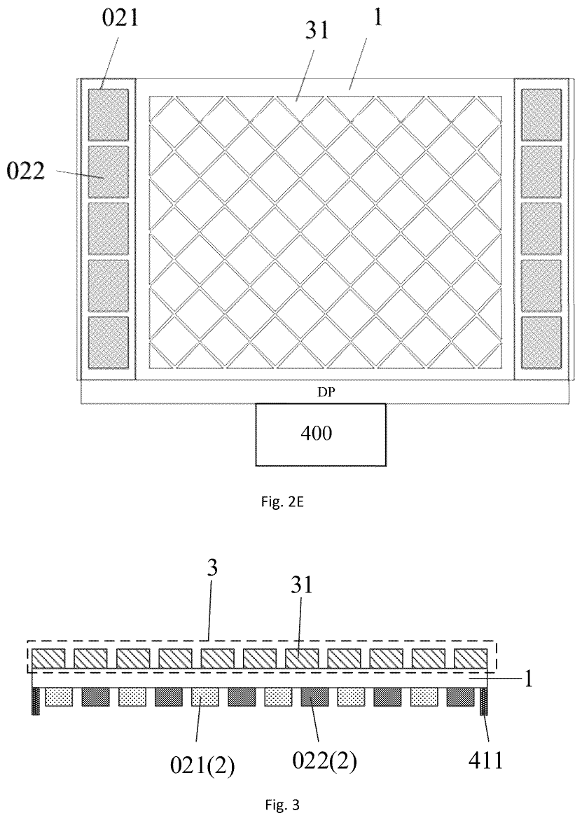

In some embodiments of the disclosure, as shown in FIGS. 2A to 3, the haptic feedback display screen 100 includes: a base substrate 1, a plurality of piezoelectric devices 2 positioned on a side of the base substrate 1 and distributed in an array, and a touch layer 3 on a side, facing away from the piezoelectric devices 2, of the base substrate 1. The piezoelectric devices 2 are configured to vibrate under the drive of the processed drive signal output by the drive circuit 400, so as to drive the base substrate 1 to vibrate. With a structure integrating the base substrate 1 and the touch layer 3, the above haptic feedback display screen 100 according to the embodiments of the disclosure may implement a touch function (e.g., determining a touch position, etc.) and a haptic reproduction function.

In some embodiments of the disclosure, as shown in FIGS. 2A to 3, the touch layer 3 is attached to a surface of the base substrate 1, so as to provide the touch position, etc, for the system in a touch process. Illustratively, the touch layer 3 is divided into a plurality of touch electrodes 31 arranged spaced from one another. Illustratively, the touch electrodes 31 may be self-capacitance touch electrodes. In this way, position coordinates of the touch position may be determined through a touch function on the basis of a self-capacitance technology. The touch electrodes 31 may also be mutual-capacitance touch electrodes. In this way, position coordinates of the touch position may be determined through a touch function on the basis of a mutual-capacitance technology.

In some embodiments of the disclosure, as shown in FIG. 2A, the piezoelectric devices 2 may be piezoelectric thin films. A given voltage signal may provide vibrational excitation directly, so that the haptic feedback display screen 100 generates a haptic feedback effect. Illustratively, the piezoelectric thin films are transparent piezoelectric thin films.

In some embodiments of the disclosure, as shown in FIGS. 2A to 3, the base substrate 1 is a substrate making direct contact with haptic sense organs such as fingers, and may be a touch panel, a display screen, etc. Specifically, the base substrate 1 may be a substrate made of glass, silicon, silicon dioxide (SiO₂), sapphire, or a metal wafer, which will not be limited herein. The base substrate is configured by a person skilled in the art according to actual application requirements.

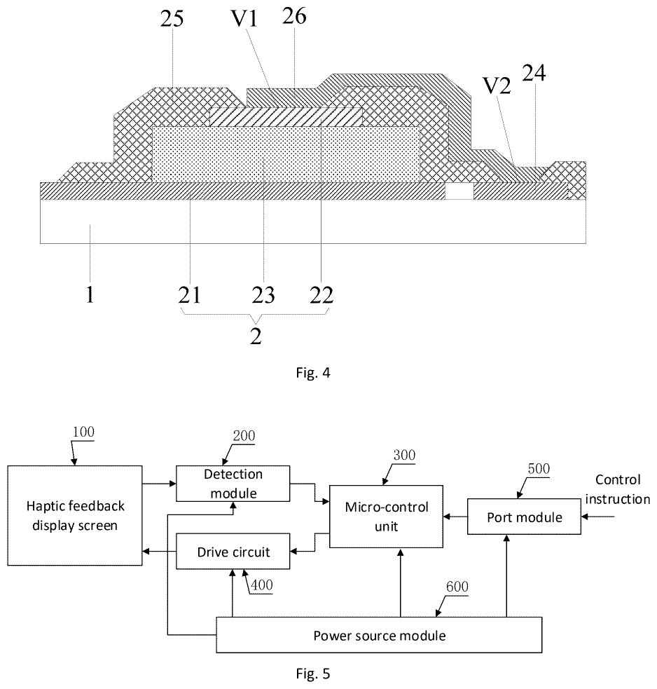

In some embodiments of the disclosure, with reference to FIG. 4, a sectional schematic structural diagram of a piezoelectric device 2 is illustrated. The piezoelectric device 2 includes: a bottom electrode 21 and a top electrode 22 that are arranged oppositely, a piezoelectric layer 23 between the bottom electrode 21 and the top electrode 22, an insulation layer 25 on a side, facing away from the piezoelectric layer 23, of the top electrode 22, and a wiring layer 26 on a side, facing away from the piezoelectric layer 23, of the insulation layer 25. The piezoelectric device 2 may further include: a bonding electrode 24 arranged at the same layer as the bottom electrode 21. The bonding electrode 24 is arranged close to an edge of the base substrate 1. The insulation layer 25 is provided with a first via hole V1 corresponding to the top electrode 22. One end of the wiring layer 26 is electrically connected to the top electrode 22 through the first via hole V1, and the other end of the wiring layer 26 is electrically connected to the bonding electrode 24 through a second via hole V2 penetrating the insulation layer 25.

In some embodiments of the disclosure, as shown in FIGS. 2A to 3, the plurality of piezoelectric devices 2 are divided into at least one haptic detection piezoelectric device 021 and at least one haptic drive piezoelectric device 022. In other words, some of the piezoelectric devices 2 may be configured as the haptic detection piezoelectric devices 021, and the rest of the piezoelectric devices 2 may be configured as the haptic drive piezoelectric devices 022. For example, one haptic detection piezoelectric device and one haptic drive piezoelectric device may be provided individually. Alternatively, a plurality of (i.e., at least two or more) haptic detection piezoelectric devices 021 and a plurality (i.e., at least two or more) of haptic drive piezoelectric devices 022 may also be provided individually. The plurality of haptic detection piezoelectric devices 021 and the plurality of haptic drive piezoelectric devices 022 are uniformly dispersed on the base substrate 1.

Optionally, as shown in FIG. 2A, the plurality of haptic detection piezoelectric devices 021 and the plurality of haptic drive piezoelectric devices 022 may be checkerboarded on the base substrate 1.

Alternatively, as shown in FIG. 2B, the plurality of haptic detection piezoelectric devices 021 may be divided into a plurality of columns, and the plurality of haptic drive piezoelectric devices 022 may also be divided into a plurality of columns. One column of haptic detection piezoelectric devices 021 and one column of haptic drive piezoelectric devices 022 are alternately arranged. Bottom electrodes 21 of one column of haptic detection piezoelectric devices 021 are arranged spaced from one another. Bottom electrodes 21 of one column of haptic drive piezoelectric devices 022 are also arranged spaced from one another. Illustratively, a number of haptic detection piezoelectric devices 021 in one column is smaller than that of haptic drive piezoelectric devices 022 in one column. Further, the piezoelectric device further includes: a lead electrode 025 arranged at the same layer as the bottom electrode 21. The lead electrode 025 is electrically connected to the bottom electrode 21 and configured to be grounded. Moreover, a lead electrode via hole 41 is provided at the position of the lead electrode 025, so that an external lead may be connected to the lead electrode 025 through a silver paste, etc.

Optionally, as shown in FIG. 2C, the plurality of haptic detection piezoelectric devices 021 may be divided into a plurality of columns, and the plurality of haptic drive piezoelectric devices 022 may also be divided into a plurality of columns. One column of haptic detection piezoelectric devices 021 and one column of haptic drive piezoelectric devices 022 are alternately arranged. Moreover, the haptic detection piezoelectric devices 021 and the haptic drive piezoelectric devices 022 are arranged in an array. Bottom electrodes 21 of one column of haptic detection piezoelectric devices 021 are electrically connected to one another. Bottom electrodes 21 of one column of haptic drive piezoelectric devices 022 are electrically connected to one another. For example, a bottom electrode 21-1 and a bottom electrode 21-2 in one column of haptic drive piezoelectric devices 022 are electrically connected to each other through a first connection portion 0221, and bottom electrodes 21-2 in one column are electrically connected to each other through a first connection portion 0221. Moreover, a bottom electrode 21-3 and a bottom electrode 21-4 in one column of haptic detection piezoelectric device 021 are electrically connected to each other through a second connection portion 0211, and the bottom electrode 21-4 and another bottom electrode 21-4 in the one column are electrically connected to each other through a second connection portion 0211.

Alternatively, as shown in FIG. 2D, the plurality of haptic detection piezoelectric devices 021 may be divided into a plurality of columns, and the plurality of haptic drive piezoelectric devices 022 may also be divided into a plurality of columns. One column of haptic detection piezoelectric devices 021 and one column of haptic drive piezoelectric devices 022 are alternately arranged. Moreover, the haptic detection piezoelectric devices 021 and the haptic drive piezoelectric devices 022 are arranged in an array. Bottom electrodes 21 of one column of haptic detection piezoelectric devices 021 are arranged spaced from one another. Bottom electrodes 21 of one column of haptic drive piezoelectric devices 022 are arranged spaced from one another. The haptic detection piezoelectric devices 021 are correspondingly connected to haptic detection signal lines 321 individually, so as to transmit signals through the haptic detection signal lines 321. The haptic drive piezoelectric devices 022 are correspondingly connected to haptic drive signal lines 322 individually, so as to transmit signals through the haptic drive signal lines 322.

Optionally, as shown in FIG. 2E, the plurality of haptic detection piezoelectric devices 021 and the plurality of haptic drive piezoelectric devices 022 may also be arranged in a non-display region of the display panel. Moreover, the haptic detection piezoelectric devices 021 and the haptic drive piezoelectric devices 022 in one column are alternately arranged. Further, the haptic detection piezoelectric devices 021 and the haptic drive piezoelectric devices 022 may be connected to the drive circuit 400 through a connection port (DP).

Certainly, the plurality of haptic detection piezoelectric devices and the plurality of haptic drive piezoelectric devices may also be arranged on the base substrate 1 in a different arrangement manner, which will not be limited by the disclosure.

Illustratively, in the haptic detection piezoelectric device 021, the bottom electrode 21 is grounded, and the bonding electrode 24 is connected to a drive detection end. When the finger touches a surface of the base substrate 1, the top electrode 22 generates a charge signal, and the charge signal may be output through the drive detection end. The detection module 200 is electrically connected to the haptic detection piezoelectric devices 021 through the haptic detection signal lines 321. In this way, the detection module 200 may detect whether the haptic feedback display screen 100 is touched by a toucher (such as the finger of the user) through the haptic detection piezoelectric devices 021, generate, in response to determining that the haptic feedback display screen 100 is touched by the toucher, a digital signal corresponding to a pressure generated when the haptic feedback display screen 100 is touched by the toucher, and send the digital signal to the micro-control unit 300. After receiving the above digital signal, the micro-control unit 300 determines whether a pressure value corresponding to the digital signal is greater than a preset value, and outputs a drive signal to the drive circuit 400 in response to determining that the pressure value corresponding to the digital signal is greater than the preset value. After processing the drive signal provided by the micro-control unit 300, the drive circuit 400 outputs a processed drive signal to the haptic drive piezoelectric devices 022 of the haptic feedback display screen 100 through the haptic drive signal lines 322.

Illustratively, in the haptic drive piezoelectric device 022, the bottom electrode 21 is grounded, and the bonding electrode 24 is connected to the signal output end of the drive circuit 400. A processed drive signal output by the signal output end of the drive circuit 400 is an alternating current voltage signal. The alternating current voltage signal (VAC) is loaded on the top electrode 22 through the bonding electrode 24. In this way, an alternating electric field may be formed between the top electrode 22 and the bottom electrode 21, and a frequency of the alternating electric field is the same as a frequency of the alternating current voltage signal. Under the action of the alternating electric field, the piezoelectric layer 23 is deformed to generate a vibration signal, and a frequency of the vibration signal is the same as the frequency of the alternating electric field. When the frequency of the vibration signal approximates or equals a natural frequency of the base substrate 1, the base substrate 1 resonates, so that a vibration amplitude is increased to generate a haptic feedback signal. When touching the surface of the base substrate 1, the finger may feel the vibration feedback obviously. In some embodiments of the disclosure, the bottom electrodes 21 and the bonding electrodes 24 may be made of the same material and formed through the same patterning process.

It should be noted that bottom electrodes 21 of all piezoelectric devices 2 in FIG. 2A may be of patterned structures or a monolithic structure. Piezoelectric layers 23 of all the piezoelectric devices 2 may be of patterned structures or a monolithic structure. Top electrodes 22 of all the piezoelectric devices 2 are of patterned structures. For example, the top electrodes 22 of all the piezoelectric devices 2 are of patterned structures corresponding one-to-one to the piezoelectric layers 22.

During implementations, the piezoelectric layers may be made of lead zirconate titanate (Pb(Zr,Ti)O₃, PZT), or at least one of aluminum nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃), and lanthanum gallium silicate (La₃Ga₅SiO₁₄), which may be specifically selected by a person skilled in the art according to actual use requirements and will not be limited herein. When the piezoelectric layers are made of PZT, with a high piezoelectric coefficient, PZT ensures a piezoelectric characteristic of the corresponding haptic feedback display screen 100. Accordingly, the corresponding haptic feedback display screen 100 may be applied to the haptic feedback devices. Moreover, when being integrated into a display device, PZT, with high light transmittance, does not affect a display quality of the display device.

During implementations, the top electrodes and the bottom electrodes of the piezoelectric devices are made of a transparent conductive material, for example, indium tin oxide (ITO) or indium zinc oxide (IZO), or one of titanium-aurum (Ti—Au) alloy, titanium-aluminum-titanium (Ti—Al—Ti) alloy, and titanium-molybdenum (Ti—Mo) alloy, or one of titanium (Ti), aurum (Au), silver (Ag), molybdenum (Mo), copper (Cu), tungsten (W), and chromium (Cr). The above transparent conductive electrodes may be configured by a person skilled in the art according to actual application requirements and will not be limited herein.

In some embodiments of the disclosure, as shown in FIGS. 2A to 3, the haptic feedback display screen further includes a support layer 4 on the base substrate 1. The support layer 4 is on the same side of the base substrate 1 as the piezoelectric device 2. Specifically, the support layer 4 is primarily configured to connect the base substrate 1 and a device. The device may be a support bezel or a support plate. Specifically, the device primarily plays a role of bearing the haptic feedback display screen 100 and may be a bezel of the display screen, a bezel of the touch panel, etc. Specifically, the device may be fixedly connected to the support layer 4 through an adhesive layer (for example, an optically clear adhesive (OCA)), etc.

In some embodiments of the disclosure, a material of the support layer 4 may include, but is not limit to, at least one of the following: rubber, polyfoam, foam, and polydimethylsiloxane (PDMS). Specifically, the support layer 4 may be fixedly connected to the base substrate 1 through an adhesive layer (for example, an optically clear adhesive (OCA)), etc. Illustratively, the support layer 4 may include a support portion 411 positioned around the base substrate 1 and arranged around all of the piezoelectric devices 2. Optionally, an orthographic projection, on the base substrate 1, of the support layer 4 (the support portion 411) is in a shape of a square, triangle, circle, trapezoid, polygon, etc. Certainly, a specific position of the support layer 4 will not be limited by the disclosure. The position of the support layer 4 may be determined according to actual application requirements and will not be limited herein.

With reference to FIG. 5, a schematic structural diagram of another haptic feedback system according to an embodiment of the disclosure is illustrated. The haptic feedback system further includes:
a port module 500, here the micro-control unit 300 receives a control instruction sent by an upper computer through the port module 500, and the micro-control unit 300 is allowed to output the drive signal or prohibited from outputting the drive signal according to the control instruction; the upper computer may be a central processing unit, an electronic control unit of a vehicle, a mobile terminal (such as a mobile phone) of the user, etc.; and the port module 500 may be a serial communication port, a Bluetooth communication port, etc., and is specifically determined according to a communication mode between the micro-control unit 300 and the upper computer; and
a power source module 600, here the power source module is configured to supply power to the haptic feedback display screen 100, the detection module 200, the micro-control unit 300, the drive circuit 400, and the port module 500.

When the haptic feedback function is set to be used by the user on the haptic feedback display screen 100, the upper computer generates permission for the micro-control unit 300 to output the drive signal in response to determining that the pressure value generated when the haptic feedback display screen is pressed by the toucher is greater than the preset value. After receiving the above drive signal, the drive circuit may process the drive signal and provide the processed drive signal to the piezoelectric device 2.

In the embodiments provided by the disclosure, by configuring the port module 500 communicating with the upper computer for the haptic feedback system, it is facilitate to set or not to set haptic feedback for the haptic feedback display screen, so that the user experience can be effectively improved.

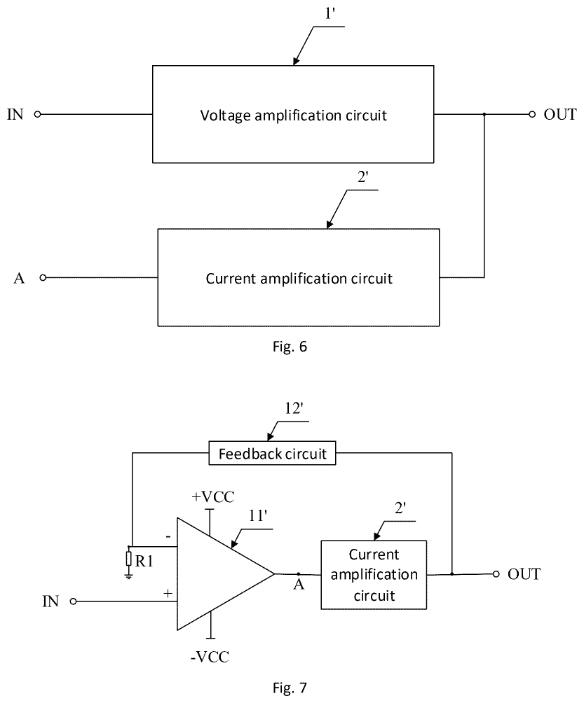

With reference to FIG. 6, a schematic structural diagram of a drive circuit according to an embodiment of the disclosure is illustrated. The drive circuit includes:
a voltage amplification circuit 1′, here the voltage amplification circuit 1′ is electrically connected to a signal input end IN and a signal output end OUT and configured to amplify a voltage at the signal input end IN and output an amplified voltage to the signal output end OUT; and
a current amplification circuit 2′, here the current amplification circuit 2′ is electrically connected to an intermediate node A and the signal output end OUT and configured to input a compensation current to the signal output end OUT, so that a current at the signal output end OUT is a sum of a current at the signal input end and the compensation current; a current at the intermediate node A equals the current at the signal input end IN.

In embodiments provided by the disclosure, configured with the voltage amplification circuit 1′ and the current amplification circuit 2′, the drive circuit may output a drive signal carrying a high current and a high voltage to at least one haptic drive piezoelectric device through mutual cooperation between the voltage amplification circuit 1′ and the current amplification circuit 2′ on the basis of a numerical value corresponding to a digital signal obtained based on a charge signal of a haptic detection piezoelectric device. Therefore, the haptic drive piezoelectric device having a large mass carrier may be driven by a driver, and a desirable vibration effect may also be realized.

With reference to FIG. 7, a schematic structural diagram of a voltage amplification circuit according to an embodiment of the disclosure is illustrated. The voltage amplification circuit 1′ includes:
an operational amplifier 11′, here a non-inverting input end + of the operational amplifier 11′ is electrically connected to the signal input end, an output end of the operational amplifier 11′ is electrically connected to the intermediate node A, and two power source ends of the operational amplifier 11′ are electrically connected to a positive power source +VCC and a negative power source-VCC respectively; the operational amplifier 11′ is configured to amplify a voltage at the signal input end IN, output an amplified voltage to the intermediate node A, and output the current at the signal input end IN to the intermediate node A; and the current amplification circuit compensates a current at the intermediate node A and outputs a compensated current to the signal output end OUT;
a feedback circuit 12′, here the feedback circuit 12′ is electrically connected to the signal output end OUT and an inverting input end-of the operational amplifier 11′ and configured to feed back a voltage at the signal output end OUT to the inverting input end of the operational amplifier 11′; and
a first resistor R1, here the first resistor is connected between the inverting input end—and a grounded end.

In embodiments provided by the disclosure, the voltage amplification circuit 1′ is configured with the operational amplifier 11′, the feedback circuit 12′, and the first resistor R1, and the feedback circuit 12′ feeds back the voltage at the signal output end OUT (i.e., the voltage amplified by the operational amplifier 11′) to the inverting input end-of the operational amplifier 11′. Accordingly, the gain of the operational amplifier 11′ is reduced, the output stability of the voltage amplification circuit 1′ is improved, and the nonlinear distortion and noise are reduced.

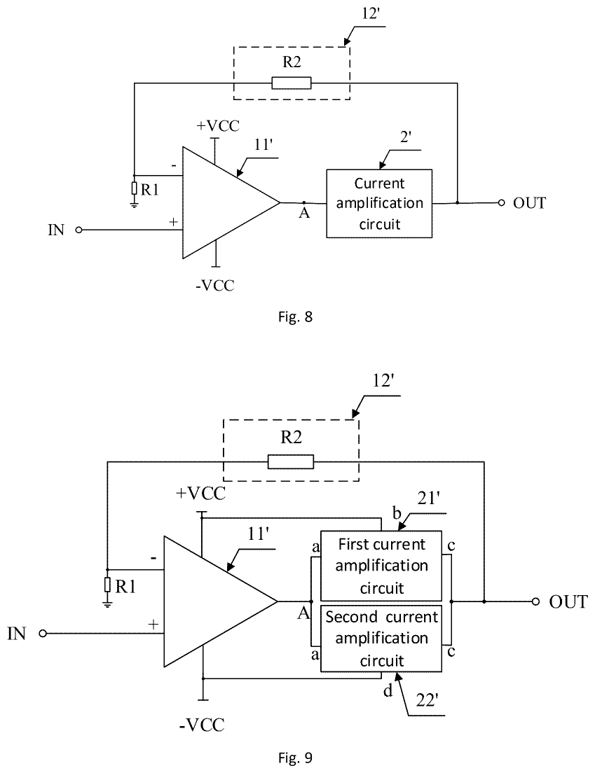

In some embodiments, the feedback circuit 12′ includes a second resistor R2. With reference to FIG. 8, a schematic structural diagram of another voltage amplification circuit according to an embodiment of the disclosure is illustrated.

In embodiments provided by the disclosure, by configuring the feedback circuit 12′ with the second resistor R2, the voltage signal feedback stability of the feedback circuit 12′ can be improved.

In some embodiments, a ratio of the voltage at the signal output end OUT to the voltage at the signal input end IN is a sum of a ratio of resistance of the second resistor R2 to resistance of the first resistor R1 and 1.

For example, if the voltage at the signal output end OUT is recorded as Vout, and the voltage at the signal input end IN is recorded as Vin,

$$Vout = Vin ( 1 + R 2 / R 1 ) .$$

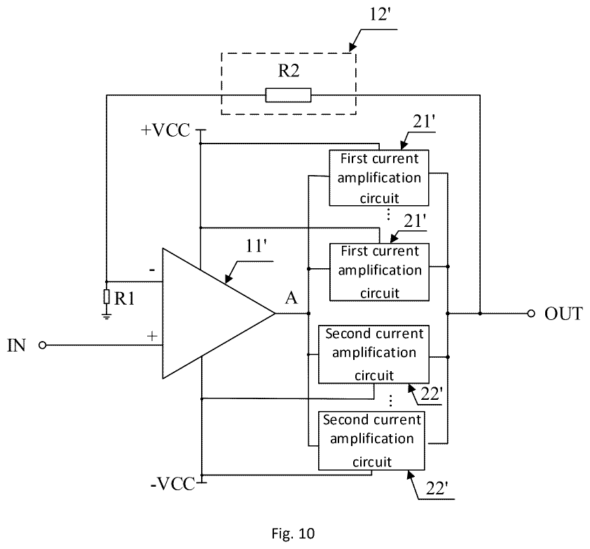

With reference to FIGS. 9 and 10, schematic structural diagrams of a current amplification circuit according to embodiments of the disclosure are illustrated. The current amplification circuit 2′ includes:
at least one first current amplification circuit 21′, here a control end a of the first current amplification circuit 21′ is electrically connected to the intermediate node A, a first end b of the first current amplification circuit 21′ is electrically connected to the positive power source +VCC, and an output end c of the first current amplification circuit 21′ is electrically connected to the signal output end OUT; and the first current amplification circuit 21′ is configured to input a compensation current greater than 0 A to the signal output end OUT in response to a potential difference between the intermediate node A and the signal output end OUT under the condition that a voltage at the intermediate node is greater than 0 V; and
at least one second current amplification circuit, here a control end a of the second current amplification circuit 22′ is electrically connected to the intermediate node A, a second end d of the second current amplification circuit 22′ is electrically connected to the negative power source-VCC, and an output end c of the second current amplification circuit 22′ is electrically connected to the signal output end OUT; and the second current amplification circuit 22′ is configured to input a compensation current smaller than 0 A to the signal output end OUT in response to a potential difference between the intermediate node A and the signal output end OUT under the condition that a voltage at the intermediate node A is smaller than 0 V.

In the embodiments provided by the disclosure, by configuring the current amplification circuit 2′ to include at least one first current amplification circuit 21′ and at least one second current amplification circuit 22′, the first current amplification circuit 21′ may be configured to compensate a current of a positive-phase signal in the drive signal and output a compensated current to the signal output end OUT. The second current amplification circuit 22′ may be configured to compensate a current of a negative-phase signal in the drive signal and output a compensated current to the signal output end OUT. Therefore, the drive circuit may provide a sufficient drive current for the haptic drive piezoelectric device.

In some embodiments, in response to determining that the current amplification circuit 2′ includes k first current amplification circuits 21′, the compensation current output by the current amplification circuit 2′ is k times a current output by one of the first current amplification circuits 21′, and k is an integer greater than 1.

For example, if I denotes the current output by the first current amplification circuit 21′, k×I denotes the current output by k first current amplification circuits 21′.

In the embodiments provided by the disclosure, by configuring the current amplification circuit 2′ to include k first current amplification circuits 21′, a capacity to compensate a positive-phase current by the current amplification circuit 2′ may be improved by k times. Accordingly, a drive capacity of the positive-phase current can be improved, and the current amplification circuit 2′ may drive a haptic drive piezoelectric device having an extremely large capacitance value or simultaneously drive a plurality of haptic drive piezoelectric devices connected in parallel.

In some other embodiments, in response to determining that the current amplification circuit 2′ includes M second current amplification circuits 22′, the compensation current output by the current amplification circuit 2′ is M times a current output by one of the second current amplification circuits 22′, and M is an integer greater than 1.

For example, if −I denotes the current output by the second current amplification circuit 22′, −M×I denotes the current output by M second current amplification circuits 22′.

In the embodiments provided by the disclosure, by configuring the current amplification circuit 2′ to include M second current amplification circuits 22′, a capacity to compensate a negative-phase current by the current amplification circuit 2′ may be improved by M times. Accordingly, a drive capacity of the negative-phase current may be improved, and the current amplification circuit 2′ may drive a haptic drive piezoelectric device having an extremely large capacitance value or simultaneously drive a plurality of haptic drive piezoelectric devices connected in parallel.

In some embodiments, a number of the first current amplification circuit 21′ equals a number of the second current amplification circuit 22′. In other words, k may be set to equal M. For example, the current amplification circuit 2′ may include two first current amplification circuits 21′ and two second current amplification circuits 22′. In this way, the capacity to compensate the current of the drive signal by the current amplification circuit 2′ can be improved by two times. Accordingly, the current amplification circuit 2′ can drive a haptic drive piezoelectric device having an extremely large capacitance value or simultaneously drive a plurality of haptic drive piezoelectric devices connected in parallel.

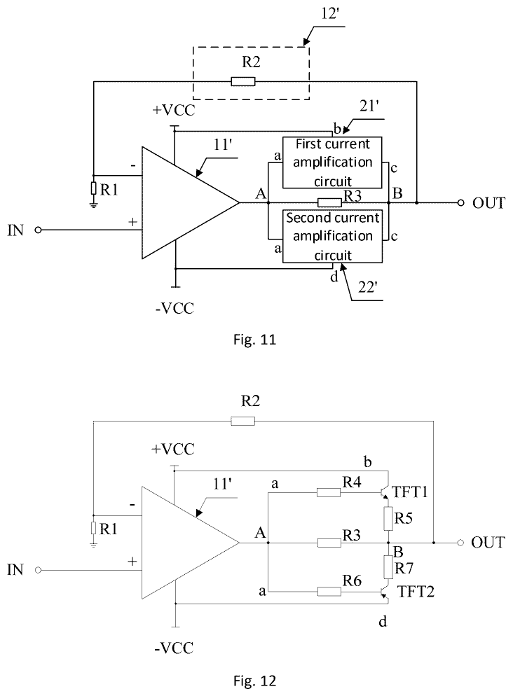

With reference to FIG. 11, a schematic structural diagram of another current amplification circuit according to an embodiment of the disclosure is illustrated. The current amplification circuit 2′ further includes:
a third resistor R3, here the third resistor R3 is electrically connected to the intermediate node A and the signal output end OUT; and the third resistor R3 is configured to hinder the potential difference between the intermediate node A and the signal output end OUT from approximating 0 V in response to determining that the first current amplification circuit or the second current amplification circuit works, and output the current at the intermediate node A to the signal output end OUT in response to determining that the first current amplification circuit or the second current amplification circuit does not work.

In some embodiments, resistance of the third resistor R3 is generally set to be small (for example, being smaller than 1 kΩ). Specific resistance of the third resistor R3 may be determined according to devices used in the first current amplification circuit 21′ and the second current amplification circuit 22′.

As shown in FIG. 11, assuming that the voltage input to the signal input end IN equals 5 V, after being amplified by 20 times by the operational amplifier 11′, the voltage at the intermediate node A equals 100 V. Assuming that the voltage input to the signal input end IN equals −5 V, after being amplified by 20 times by the operational amplifier 11′, the voltage at the intermediate node A equals −100 V. Since the resistance of the third resistor R3 is smaller than 1 kΩ, a voltage ratio of the third resistor R3 is small. It may be approximately deemed that the voltage at the intermediate node A basically equals a voltage at node B. After the current at the intermediate node A is compensated by the first current amplification circuit 21′ and the second current amplification circuit 22′, the processed drive signal having the same voltage as the intermediate node A but an amplified current drive capacity is formed at the node B and output through the signal output end.

Although approximating 0 V, a potential difference exists between the intermediate node A and the node B. When the voltage at the intermediate node A is greater than 0 V, owing to the potential difference between the intermediate node A and the node B, the first current amplification circuit 21′ may be turned on, and the first end b and the output end c of the first current amplification circuit 21′ are connected to each other. Therefore, a channel from the positive power source +VCC to the signal output end OUT via the first end b of the first current amplification circuit 21′ is formed to compensate the current of the drive signal, so that a function of amplifying the positive-phase current of the drive signal is realized. Similarly, when the voltage at the intermediate node A is smaller than 0 V, owing to the potential difference between the intermediate node A and the node B, the second current amplification circuit 22′ may be turned on, and the second end d and the output end c of the second current amplification circuit 22′ are connected to each other. Therefore, a channel from the negative power source −VCC to the signal output end OUT via the second end d of the second current amplification circuit 22′ is formed to compensate the current of the drive signal, so that a function of amplifying the negative-phase current of the drive signal is realized.

In the embodiments provided by the disclosure, by configuring the third resistor R3 between the intermediate node A and the signal output end OUT, the first current amplification circuit 21′ or the second current amplification circuit 22′ may be turned on in time according to a phase of the drive signal. Therefore, the current of the drive signal may be compensated in time, and the drive circuit may compensate an appropriate current according to the change in a load.

With reference to FIG. 12, a schematic structural diagram of a first current amplification circuit according to an embodiment of the disclosure is illustrated. The first current amplification circuit 21′ in the drive circuit includes:
a first thin film transistor TFT1, here a first electrode of the first thin film transistor TFT1 is electrically connected to the positive power source +VCC;
a fourth resistor R4, here the fourth resistor R4 is electrically connected between the intermediate node A and a control electrode of the first thin film transistor TFT1 and configured to limit a current flowing into the control electrode of the first thin film transistor TFT1;
a fifth resistor R5, here the fifth resistor is electrically connected between a second electrode of the first thin film transistor TFT1 and the signal output end OUT.

The first thin film transistor TFT1 is configured to connect the first electrode and the second electrode of the first thin film transistor TFT1 in response to the potential difference between the intermediate node A and the signal output end OUT under the condition that the voltage at the intermediate node A is greater than 0 V. Therefore, the signal output end OUT compensates the current through the channel formed among the first electrode, the second electrode, and the fifth resistor R5. When the voltage at the intermediate node A is greater than 0 V, the potential difference between the intermediate node A and the signal output end OUT is generally greater than or equal to a turn-on voltage of the first thin film transistor TFT1. If the turn-on voltage of the first thin film transistor TFT1 equals 0.7 V, the potential difference between the intermediate node A and the signal output end OUT is greater than or equal to 0.7 V.

The second current amplification circuit 22′ includes:
a second thin film transistor TFT2, here a first electrode of the second thin film transistor TFT2 is electrically connected to the negative power source −VCC;
a sixth resistor R6, here the sixth resistor R6 is connected between the intermediate node A and a control electrode of the second thin film transistor TFT2 and configured to limit a current flowing into the control electrode of the second thin film transistor TFT2; and
a seventh resistor R7, here the seventh resistor is connected between a second electrode of the second thin film transistor TFT2 and the signal output end OUT.

The second thin film transistor TFT2 is configured to connect the first electrode and the second electrode of the second thin film transistor TFT2 in response to the potential difference between the intermediate node A and the signal output end OUT under the condition that the voltage at the intermediate node A is smaller than 0 V. Therefore, the signal output end OUT compensates the current through the channel formed among the first electrode, the second electrode, and the seventh resistor R7. When the voltage at the intermediate node A is smaller than 0 V, the potential difference between the intermediate node A and the signal output end OUT is generally smaller than or equal to a turn-on voltage of the second thin film transistor TFT2. If the turn-on voltage of the second thin film transistor TFT2 equals −0.7 V, the potential difference between the intermediate node A and the signal output end OUT is smaller than or equal to −0.7 V.

In the embodiments provided by the disclosure, by configuring the first current amplification circuit 21′ to include the first thin film transistor TFT1, the fourth resistor R4, and the fifth resistor R5, the first thin film transistor TFT1, the fourth resistor R4, and the fifth resistor R5 cooperate with one another to compensate the positive-phase current of the drive signal and output a compensated positive-phase current to the signal output end OUT. By configuring the second current amplification circuit 22′ to include the second thin film transistor TFT2, the sixth resistor R6, and the seventh resistor R7, the second thin film transistor TFT2, the sixth resistor R6, and the seventh resistor R7 cooperate with one another to compensate the negative-phase current of the drive signal and output a compensated negative-phase current to the signal output end OUT. Accordingly, the current of the drive signal may be compensated, and the current amplification circuit 2′ may drive the haptic drive piezoelectric device having a large capacitance value.

In some embodiments, the first thin film transistor TFT1 and the second thin film transistor TFT2 are transistors having opposite polarities. If the first thin film transistor TFT1 is an N-type transistor, the second thin film transistor TFT2 is a P-type transistor.

In the embodiments provided by the disclosure, the first thin film transistor TFT1 and the second thin film transistor TFT2 are configured as the transistors having the opposite polarities, so that the positive-phase current and the negative-phase current of the drive signal may be amplified equivalently.

In some embodiments, the first thin film transistor TFT1 and the second thin film transistor TFT2 are bipolar junction transistors. If the first thin film transistor TFT1 is an NPN bipolar junction transistor, the second thin film transistor TFT2 is a PNP bipolar junction transistor.

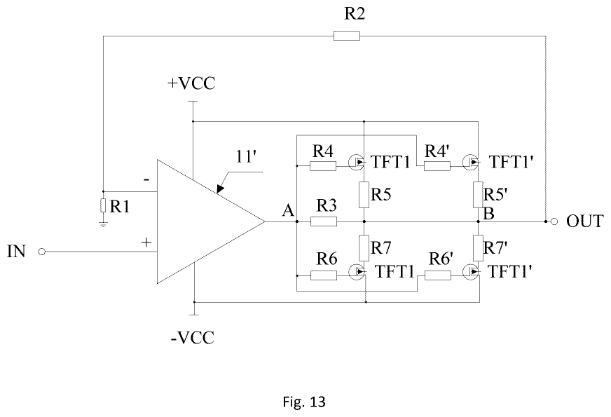

In some other embodiments, the first thin film transistor TFT1 and the second thin film transistor TFT2 are metal-oxide-semiconductor field-effect transistors (MOSFETs). If the first thin film transistor TFT1 may be an N-metal-oxide-semiconductor (NMOS) transistor, the second thin film transistor TFT2 may be a P-metal-oxide-semiconductor (PMOS) transistor. With reference to FIG. 13, a schematic structural diagram of another drive circuit according to an embodiment of the disclosure is illustrated. In FIG. 13, a first thin film transistor TFT1 and a second thin film transistor TFT2 may be MOS transistors, and a current amplification circuit 2 includes, for example, two first thin film transistors TFT1 and two second thin film transistors TFT2.

In the embodiments provided by the disclosure, the first thin film transistors TFT1 and the second thin film transistors TFT2 are configured as the MOS transistors, so that the stability of the current amplification circuit 2′ can be improved. Since sources and drains of the MOS transistors may be used interchangeably, the configuration flexibility of the current amplification circuit 2′ can be improved, a size, a weight, noise, and power consumption of the current amplification circuit 2′ can be reduced, a service life of the current amplification circuit 2′ can be prolonged, and the input impedance, thermal stability, and interference resistance of the current amplification circuit can be improved.

In some other embodiments, the metal-oxide-semiconductor field-effect transistors include an enhancement mode metal-oxide-semiconductor field-effect transistor and a depletion mode metal-oxide-semiconductor field-effect transistor.

In the embodiments provided by the disclosure, the MOS transistors are configured as the depletion mode MOS transistors. Since voltages at control electrodes of the MOS transistors may be positive or negative, the current amplification circuit 2′ including the MOS transistors is more flexible to configure, and the voltage is controlled in a more convenient manner.

Although the preferred embodiments of the present disclosure have been described, a person skilled in the art can make additional changes and modifications to these embodiments once they learn the basic creative concepts. Thus, it is intended that the appended claims are to be interpreted as including the preferred embodiments and all changes and modifications falling within the scope of the disclosure.

Obviously, a person skilled in the art can make various amendments and variations to the disclosure without departing from the spirit and scope of the disclosure. In this way, the disclosure is also intended to encompass these amendments and variations to the disclosure if these amendments and variations fall within the scope of the claims of the disclosure and their equivalents.

1-17. (canceled)

18. A drive circuit, comprising:
a voltage amplification circuit, wherein the voltage amplification circuit is electrically connected to a signal input end and a signal output end and configured to amplify a voltage at the signal input end and output an amplified voltage to the signal output end; and
a current amplification circuit, wherein the current amplification circuit is electrically connected to an intermediate node and the signal output end and configured to input a compensation current to the signal output end, so that a current at the signal output end is a sum of a current at the signal input end and the compensation current, and a current at the intermediate node equals the current at the signal input end.

19. The drive circuit according to claim 18, wherein the voltage amplification circuit comprises:
an operational amplifier, wherein a non-inverting input end of the operational amplifier is electrically connected to the signal input end, an output end of the operational amplifier is electrically connected to the intermediate node, and two power source ends of the operational amplifier are electrically connected to a positive power source and a negative power source respectively;
a feedback circuit, wherein the feedback circuit is electrically connected to the signal output end and an inverting input end of the operational amplifier and configured to feed back a voltage at the signal output end to the inverting input end of the operational amplifier; and
a first resistor, wherein the first resistor is connected between the inverting input end and a grounded end.

20. The drive circuit according to claim 19, wherein the feedback circuit comprises a second resistor.

21. The drive circuit according to claim 18, wherein the current amplification circuit comprises:
at least one first current amplification circuit, wherein a control end of the first current amplification circuit is electrically connected to the intermediate node, a first end of the first current amplification circuit is electrically connected to a positive power source, and an output end of the first current amplification circuit is electrically connected to the signal output end; and the first current amplification circuit is configured to input a compensation current greater than 0 A to the signal output end in response to a potential difference between the intermediate node and the signal output end under a condition that a voltage at the intermediate node is greater than 0 V; and
at least one second current amplification circuit, wherein a control end of the second current amplification circuit is electrically connected to the intermediate node, a second end of the second current amplification circuit is electrically connected to a negative power source, and an output end of the second current amplification circuit is electrically connected to the signal output end; and the second current amplification circuit is configured to input a compensation current smaller than 0 A to the signal output end in response to a potential difference between the intermediate node and the signal output end under a condition that a voltage at the intermediate node is smaller than 0 V.

22. The drive circuit according to claim 21, wherein the current amplification circuit further comprises:
a third resistor, wherein the third resistor is electrically connected to the intermediate node and the signal output end; and the third resistor is configured to hinder the potential difference between the intermediate node and the signal output end from approximating 0 V in response to determining that the first current amplification circuit or the second current amplification circuit works, and output the current at the intermediate node to the signal output end in response to determining that the first current amplification circuit or the second current amplification circuit does not work.

23. The drive circuit according to claim 21, wherein the first current amplification circuit comprises:
a first thin film transistor, wherein a first electrode of the first thin film transistor is electrically connected to the positive power source;
a fourth resistor, wherein the fourth resistor is electrically connected between the intermediate node and a control electrode of the first thin film transistor; and
a fifth resistor, wherein the fifth resistor is electrically connected between a second electrode of the first thin film transistor and the signal output end.

24. The drive circuit according to claim 23, wherein the second current amplification circuit comprises:
a second thin film transistor, wherein a first electrode of the second thin film transistor is electrically connected to the negative power source;
a sixth resistor, wherein the sixth resistor is connected between the intermediate node and a control electrode of the second thin film transistor; and
a seventh resistor, wherein the seventh resistor is connected between a second electrode of the second thin film transistor and the signal output end.

25. The drive circuit according to claim 24, wherein resistance of the fourth resistor equals resistance of the sixth resistor; and
resistance of the fifth resistor equals resistance of the seventh resistor.

26. The drive circuit according to claim 25, wherein the first thin film transistor and the second thin film transistor are bipolar junction transistors or metal-oxide-semiconductor field-effect transistors.

27. The drive circuit according to claim 26, wherein the metal-oxide-semiconductor field-effect transistors comprise an enhancement mode metal-oxide-semiconductor field-effect transistor and a depletion mode metal-oxide-semiconductor field-effect transistor.

28. The drive circuit according to claim 22, wherein resistance of the third resistor is smaller than 1 kΩ.

29. The drive circuit according to claim 22, wherein in response to determining that the current amplification circuit comprises k first current amplification circuits, the compensation current output by the current amplification circuit is k times a current output by one of the first current amplification circuits, and k is an integer greater than 1.

30. The drive circuit according to claim 21, wherein in response to determining that the current amplification circuit comprises M second current amplification circuits, the compensation current output by the current amplification circuit is M times a current output by one of the second current amplification circuits, and M is an integer greater than 1.

31. The drive circuit according to claim 21, wherein a quantity of the first current amplification circuits equals a quantity of the second current amplification circuits.

32. The drive circuit according to claim 20, wherein a ratio of the voltage at the signal output end to the voltage at the signal input end is a sum of a ratio of resistance of the second resistor to resistance of the first resistor and 1.

33. A haptic feedback system, comprising:
a haptic feedback display screen;
a detection module, wherein the detection module is configured to detect whether the haptic feedback display screen is touched by a toucher and generate a digital signal in response to determining that the haptic feedback display screen is touched by the toucher;
a micro-control unit, wherein the micro-control unit is configured to determine whether a numerical value corresponding to the digital signal is greater than a preset value after receiving the digital signal, and output a drive signal in response to determining that the numerical value is greater than the preset value; and
the drive circuit according to claim 18, wherein the drive circuit is configured to receive the drive signal through the signal input end, process the drive signal, and output a processed drive signal to the haptic feedback display screen through the signal output end, so as to drive the haptic feedback display screen to work.

34. The haptic feedback system according to claim 33, further comprising:
a port module, wherein the micro-control unit receives a control instruction sent by an upper computer through the port module, and the micro-control unit is allowed to output the drive signal or prohibited from outputting the drive signal according to the control instruction; and
a power source module, wherein the power source module is configured to supply power to the haptic feedback display screen, the detection module, the micro-control unit, the drive circuit, and the port module.
